(19) United States
(12) Patent Application Publication
(10) Pub. No.: US 2007/0047291 A1
(43) Pub. Date: Mar. 1, 2007

(54) Integrated memory circuit comprising a resistive memory element and a method for manufacturing such a memory circuit

(76) Inventor: Heinz Hoenigschmid, Poecking (DE)

Correspondence Address: PATTERSON & SHERIDAN, LLP;Gero McClellan / Infineon / Qimonda, 3040 POST OAK BLVD.,, SUITE 1500, HOUSTON, TX, 77056, US

(21) Appl. No.: 11/213,560

(22) Filed: Aug. 26, 2005

(51) Int. Cl. G11C 11/00

(52) U.S. Cl. 365/148

(57) ABSTRACT

The present invention relates to an integrated memory circuit for storing information, the memory circuit comprising a memory cell having a memory element with a first contact for connecting to a write/read unit and a second contact for connecting to a reference potential provided by a potential source and a resistive connecting element provided with a programmable resistance connected between the potential source to the second contact.

### BACKGROUND OF THE INVENTION

1. Field of the Invention

The present invention relates to an integrated memory circuit comprising a resistive memory element, in particular a conductive bridging random access memory (CBRAM) element. The invention further relates to a method for manufacturing such a memory circuit.

2. Description of the Related Art

Novel integrated memory circuits comprise resistive memory elements, the resistance values of which may be programmed individually whereby information may be stored. Such resistive memory elements may, for example, be CBRAM memory elements (e.g., programmable metallization cell (PMC) memory elements), phase change memory elements and magneto-resistive memory elements.

Such a resistive memory element is typically coupled to a bit line, either directly or via a selection transistor, by its first contact and connected to a constant reference potential by its second contact. In the case of a plurality of memory elements, the respective second contacts are connected to a common connecting unit, to which the reference potential is applied. The common connecting unit is typically configured as a laminar layer disposed above the memory cells and to which the reference potential is applied.

Such an integrated memory circuit usually comprises switching elements on the surface of a substrate, which have been manufactured by CMOS technology or a similar technology suitable for integrating electrical circuits, including, for example, the selection transistors of the memory cells, as well as an address decoding circuit and other components necessary for the functionality of the memory circuits.

Subsequently, materials for forming resistive memory elements are deposited in a structured manner by means of conventional masking and depositing processes. Since the second contacts of the resistive memory elements typically have to be contacted only via the surface, a metal layer is then deposited for manufacturing the connecting unit, and the common connecting unit is connected to a reference potential by means of vias through an insulating layer. The manufacturing of the through-vias requires process steps which may affect or degrade the functionality of the resistive memory elements. In particular, the functionality of the resistive memory elements is strongly affected through the use of a thermal step. However, so far there is no suitable alternative method for connecting the common connecting unit of the resistive memory elements to a conductor structure disposed between the resistive memory elements and the substrate surface. In particular, making contact through the plane in which the resistive memory elements are provided may only be realized currently by means of process steps which would retroactively affect or degrade the functionality of the resistive memory elements.

### SUMMARY OF THE INVENTION

One aspect of the present invention provides an integrated memory circuit which may be manufactured without process steps that may adversely affect or degrade the already existing resistive memory elements. Another aspect of the present invention to provides a method for manufacturing the integrated memory circuit in which simplifies the process for making the contacts to the joint connecting unit.

In a first aspect, the present invention provides an integrated memory circuit for storing information. The integrated memory circuit comprises a memory cell having a memory element with a first contact for connecting to a write/read unit and a second contact for connecting to a reference potential. A voltage source provides the reference potential for the second contact. A resistive connecting element comprising a programmable resistance is provided to connect the voltage source to the second contact. The memory element is particularly configured as an element with a programmable resistance which, depending on the programmed state, exhibits a high resistive or a low resistive state.

Accordingly, in an integrated memory circuit comprising a memory cell in which a memory element has to be connected to a reference potential, the reference potential may be provided to the memory element via a programmable resistive connecting element.

Thus, when the memory elements are also configured as programmable resistive memory elements, an additional processing for manufacturing a suitable contacting of the second contact of the memory element is not required. Thereby, the memory element is not affected in its functionality by subsequent process steps, e.g., the processing means, temperatures, pressures and other factors used in the process steps, since these subsequent process steps have been eliminated.

The connecting element may be configured similarly to the memory element, and the second contact of the memory element and a second contact of the connecting element are connected to each other, wherein the connecting element is in a low resistive state. In this manner, the connecting element may be produced along with the memory element in the same process steps, so that no additional process steps are required for manufacturing the connecting element.

In one embodiment, at least one of the memory elements and the connecting elements is a magneto-resistive element, a phase change element or a CBRAM element. These elements have an electrical resistance depending on the programmed state and are therefore suitable for use as resistive memory elements.

According to one embodiment, the memory element and the connecting element are disposed in a first layer structure on a substrate. In particular, the first contact of the memory element may be configured in such a way that it can be coupled to a bit line, and the potential source may be connected to the second contact via a conductor element The bit line and the conductor element may be formed in a second layer structure, which is arranged between the first layer structure and a substrate surface. Thus, the bit line and the conductor element for providing the reference potential may also be manufactured by means of the same process steps.

The memory element may be coupled to the bit line by means of a selection transistor provided on the substrate surface.

Alternatively, the connecting element may be coupled to the bit line via a conductive area provided on the substrate surface, the conductive region being configured similarly to a source or drain region of the selection transistor. The conductive area may thus be configured as a doping area within the substrate, so that the conductive area and the doping regions of the source and drain regions of the selection transistor may be manufactured by means of the same process steps.

The first contact of the memory element may be coupled to a conducting area and the potential source may be connected to the second contact via a conductor element, the conducting area and the conductor element being formed in a second layer structure. In particular, the memory element may be adapted to be coupled to a bit line formed in a third layer structure via the conducting region via a selection transistor provided on the substrate surface, the third layer structure being arranged between the second layer structure and a substrate surface. In this way, a contacting of the memory element's second contact by means of the conductor element may be provided, whereby the reference potential does not have to be guided over a conductive area on the substrate surface. Thus, the conducting element may be coupled via the conductor element without crossing the third layer structure.

According to one embodiment of the present invention, a plurality of memory cells is provided, the second contact of the respective memory elements being in contact with each other via a common connecting unit. A plurality of connecting elements may be provided to apply the reference potential to the common connecting unit. In particular, the plurality of connecting elements is connected to the connecting unit at various positions, so that when a current flows through one or several of the memory elements, a voltage drop over the area of the connecting unit which is greater than a predetermined value is prevented.

According to one embodiment, an initializing unit may be provided which can be coupled to the first contacts of the contacting elements to set the connecting elements from an originally high resistive state to a low resistive state in an initializing process. Such an initializing unit is particularly necessary in such resistive connecting elements which after manufacture are at first in a high resistive state and thus have to be transferred into a lower resistive state so that the second contacts of the memory elements are set to a constant reference potential.

In particular, the initializing unit may comprise a selection unit for selecting one or more of the connecting elements being in a high resistive state for programming them to a low resistive state, and a programming unit for applying a programming potential provided by the initializing unit between the first contact of the one or more selected connecting elements and the first contact of the unselected connecting elements, so that at least the selected connecting element(s) is/are programmed to the low resistive state. Thereby, the selected connecting elements and the unselected connecting elements form a voltage divider, in which the selected connecting element(s) is/are connected in parallel to each other and are connected in series to the parallel-connected unselected connecting elements. Since the total resistance of the selected connecting element or, respectively, of the selected connecting elements connected in parallel to each other is sufficiently high that a voltage acts over the selected connecting elements when the programming potential is applied, resulting in the selected connecting elements being programmed from the high resistive state to the low resistive state.

According to a further aspect of the present invention, a method is provided for initializing an integrated memory circuit comprising a plurality of memory elements and a plurality of connecting elements, the second contacts of which are connected to each other via a common connecting unit, the connecting elements being configured as CBRAM elements, whereby the connecting elements are each in a high resistive state after manufacturing of the integrated circuit. To initialize the integrated memory circuit, one or more of the connecting elements in a high resistive state are selected for programming to a low resistive state, and subsequently, a programming potential is applied between the first contacts of the one or more of the selected connecting elements and the first contacts of the unselected connecting elements to program at least the selected connecting element(s) to a low resistive state.

The application of a potential over the connecting elements serves to program the connecting elements in an appropriate manner so that at least the selected connecting elements may be transferred to a low resistive state. Thus, it is possible to change the resistance of the connecting elements, which are formed as programmable resistive elements and which are in a high resistive state after manufacture, in such a way that a low resistive contact enables the second contact to be connected to the reference potential.

According to one embodiment of the invention, the steps of selecting the one or more of the connecting elements and of applying the programming potential are repeated until the connecting elements are in a low resistive state.

The programming potential is selected in such a way that a voltage drop occurs at least over the selected connecting elements(s), which is sufficient for setting the connecting element to a low resistive state.

According to another aspect of the present invention, a method is provided for manufacturing an integrated memory circuit comprising a memory cell having a memory element with a first contact for connecting to a write/read unit and a second contact for connecting to a reference potential. The method comprises providing a substrate, manufacturing one or more conductor layers to form a bit line and a conducting element which is isolated therefrom, depositing a connecting element with a programmable resistance, depositing a memory element so that the first contact of the memory element may be coupled to the bit line, the connecting element being deposited in such a way that it is connected to the conducting element and that the second contact of the memory element is connectable to the reference potential via the connecting element.

The memory element is configured as an element with a programmable resistance exhibiting a high resistive or a low resistive state depending on the programming state. The connecting element and the memory element may be formed in a common manufacturing step in a first layer structure on the substrate.

In one aspect, after manufacturing of the memory element, which according to another embodiment may also be configured as an element with a programmable resistance, no further or subsequent process steps are required which may adversely affect the functionality of the memory elements due to the process means, temperatures, pressures, etc., employed therein.

A connecting element may be set from a high resistive state to a low resistive state during a programming step after formation of the connecting element.

The bit line and the conductor element may be formed in a common manufacturing step in a second layer structure which is arranged between the first layer structure and a substrate surface. In particular, a selection transistor may be provided in the substrate, whereby the memory element is formed or deposited in such a way that the memory element may be coupled to the bit line via the selection transistor.

According to one embodiment, in particular during the manufacturing of the selection transistor, a conductive region may be provided in the substrate surface during the same process, whereby the connecting element and the conductor element are coupled to each other via the conductive region.

According to an alternative embodiment, a conducting area may be provided when manufacturing the conductor layers, and the memory element is deposited onto the conducting area so that a first contact is connected to the conducting area. A conductor element is provided to connect the reference potential to the second contact of the memory element via the conductor element, wherein the conducting area and the conductor element being formed in a second layer structure.

According to one embodiment of the invention, a selection transistor may be provided in the substrate, the memory element being arranged in such a way that it can be coupled to a bit line formed in a third layer structure via the selection transistor, wherein the third layer structure is arranged between the second layer structure and a substrate surface. The connecting element is arranged in such a way that it is coupled to the conductor element without crossing the third layer structure.

According to a further embodiment, a plurality of memory cells may be provided, the respective memory elements of which are connected to each other by their second contacts. A plurality of connecting elements may be provided to connect the reference potential to the second contacts of the memory elements. Particularly, a conductive connecting unit may be provided by means of which the second contacts of the memory elements are connected to each other. The plurality of connecting elements are connected to the connecting unit at various positions so that when current flows through one or more of the memory elements, a voltage drop over the area of the connecting unit which is greater than a predetermined value is prevented.

By means of an initializing process, the connecting elements may be set from a high resistive state to a low resistive state. The initializing process may comprise the steps of selecting one or more of the connecting elements in a high resistive state for programming to a low resistive state, and applying a programming potential between the first contact of the one or more of the selected connecting elements and the first contact of the unselected connecting elements to program the selected connecting element(s) to the low resistive state. These steps may be repeated until all of the connecting elements are programmed to a low resistive state.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a circuit diagram for a memory cell comprising a programmable resistive memory element;

FIG. 2 is a voltage-current-diagram for a resistive CBRAM memory element;

FIG. 3 is a cross-section of a substrate comprising an integrated memory circuit realizing a memory arrangement according to the prior art;

FIG. 4 is a cross-section of a substrate comprising an integrated memory circuit according to a first embodiment of the present invention;

FIG. 5 is a cross-section of a substrate comprising an integrated memory circuit according to a further embodiment of the present invention;

FIG. 6 is a schematic top view of a memory cell arrangement of an integrated memory circuit, in which a reference potential is provided to the memory cells via a connecting plate;

FIG. 7 is a circuit diagram of a section from an integrated memory circuit showing an initializing unit by means of which the connecting elements may be set from a high resistive state to a low resistive state.

### DETAILED DESCRIPTION OF THE PREFERRED EMBODIMENT

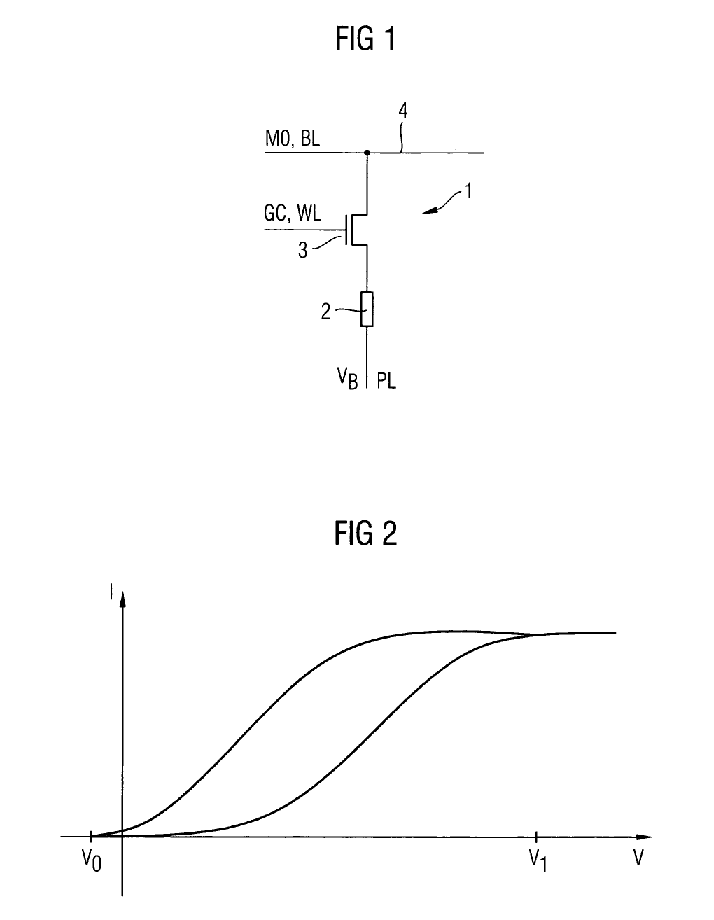

FIG. 1 shows a schematic view of a circuit diagram for a memory cell 1 comprising a programmable resistive memory element 2 which is connected to a bit line BL by means of a selection transistor 3. The selection transistor 3, e.g., a field effect transistor, is thereby connected to the bit line BL by a first contact and to a first contact of the resistive memory element 2 by a second contact. A second contact of the resistive memory element 2 is connected to a reference potential V_{B}. A control contact of the selection transistor 3 may be accessed via a word line WL. Typically, in integrated memory circuits the reference potential V_{B} is provided to all memory cells of a memory cell array via a connecting plate PL. The reference potential is provided by a potential source (not shown) which may be located inside or outside of the memory circuit.

The resistive memory element 3 may comprise an element with a variable resistance which is set to high or low depending on the programmed state. Examples for such a resistive memory element are magneto-resistive memory elements, CBRAM elements (e.g., PMC elements) and phase change elements. In a magneto-resistive element, the resistance of the memory element depends on the direction of magnetization of two adjacent magnetizable materials. The magnetization of the materials takes place either in the same or in the opposite direction to achieve various resistive values of the memory element. In a phase change element, the resistance depends on a phase state of the resistive material which varies depending on whether the resistive material is cooled quickly or slowly after heating in a programming process. In a CBRAM element, the electric resistance value depends on the formation of a conductive path in a solid electrolyte material (e.g., chalcogenides), which is built up or degraded by applying an electric field, whereby the resistance of the CBRAM memory element is altered as a result.

Data is written into a CBRAM memory cell by at first disabling the selection transistor through activation of the word line WL and by applying a corresponding write or read potential to the bit line so that a corresponding write or read voltage acts upon the CBRAM memory element.

In the following, embodiments of the invention are described using the example of CBRAM memory elements which are representative for all other programmable resistive memory elements.

As shown in FIG. 2, a CBRAM memory element exhibits a voltage-current diagram with a hysteresis, wherein a first state is written into the CBRAM memory cell upon application of a voltage larger than a first threshold value V₁, wherein a second state can be written into the CBRAM memory cell upon application of a negative voltage V₀, and wherein the CBRAM memory cell can be read out without affecting the information stored therein when a read voltage is applied which is defined in a particular voltage range in which the hysteresis is pronounced.

In a memory cell arrangement comprising a plurality of memory cells, the second contacts of the memory elements are typically connected to each other via the connecting unit, such as a plane conductive layer, so that all memory cells are connected to the same reference potential and that the plurality of memory cells can be read out and written into with generally the same bit line potentials.

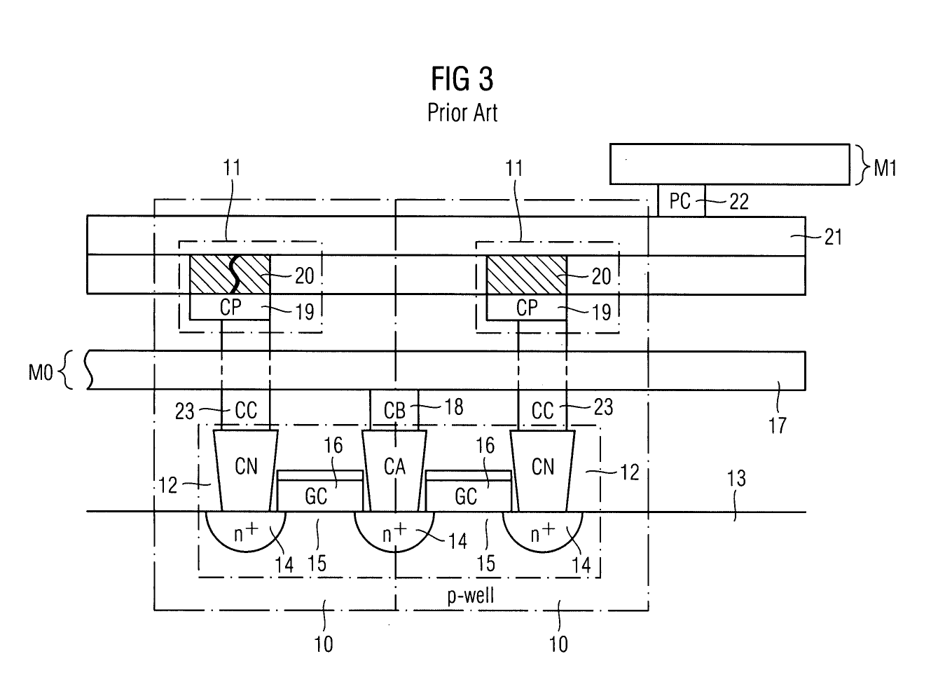

FIG. 3 shows a cross-section of a memory cell arrangement of an integrated memory circuit comprising CBRAM memory elements according to the prior art. Two adjacent memory cells 10 are shown, each comprising a CBRAM memory element 11 and a selection transistor 12.

In detail, doping or diffusion regions 14 are disposed in a substrate surface 13 by means of suitable doping processes. In between, a respective channel region 15 is situated over which a word line 16 runs, e.g., insulated by a gate oxide (not shown). The selection transistor 12 is appropriately insulated from a first metallization layer M0 situated above, in which the bit line 17 is formed. The bit line 17 is in contact with a read/write unit (not shown) to carry out a reading or writing operation to the CBRAM memory cells. One of the diffusion regions 14, the middle region in the shown embodiment, is connected to the bit line 17 via a through-via 18 (CA, CB). The respective other diffusion regions 14, which are connected to the middle diffusion region 14 via the channel region 15, are connected to the CBRAM memory element 11 by means of a suitable through-via 23 (CN, CC) without producing an electrical contact with the bit line 17. The through-connection 23 reaching from the doping region 14 to the first contact region 19 of the CBRAM memory elements is produced in such a way that no electrical contact to the bit line exists, i.e., in front or behind the bit line with reference to the illustrated plane. As illustrated, the word lines run essentially perpendicularly to the illustrated plane.

The CBRAM memory elements 11 each comprise a first contact region 19 which serves, for example, as an ion source for the solid electrolyte material (e.g., chalcogenides) in an electrolyte region 20. Above the electrolyte region 20 (with respect to the substrate surface 13), a connecting plate 21 (also referred to as a common connecting unit) is configured as a cohesive conductive layer which serves as a second electrode for the CBRAM memory elements. The first contact region 19 may comprise silver, and the solid electrolyte may comprise germanium-selenide. Upon application of an electric field, silver ions may diffuse into the solid electrolyte or may be driven out of the solid electrolyte, depending on the polarity of the electric field. Other materials for the electrode and the solid electrolyte which are suitable for forming the CBRAM memory element are also contemplated.

In the prior art as shown in FIG. 3, the contacting of the connecting plate 21 is carried out via a second metallization layer M1 which, as a potential source, provides the reference potential to the connecting plate 21 by a through-via 22. The through-via 22 is in contact with a potential source (not shown) which is provided within or outside of the integrated circuit.

In the use of conventional process technologies, e.g., on the basis of silicon as a substrate material, the deposition of a metallization layer, the manufacturing of through-vias and other subsequent process steps (i.e., subsequent to the formation of the memory elements), the process means, temperatures, pressures and other process conditions employed therein may result in the functionality of the already existing CBRAM memory elements 11 being adversely affected or degraded. In particular, the thermal step, which is necessary in the formation of the through-vias, has the effect that, in the above-mentioned material system, the silver ions in the solid electrolyte form a ternary bond with germanium and selenium, thereby destroying the desired programmability. Even producing a through-via through the connecting plate and the layer in which the memory elements are arranged in the direction of the substrate surface would require such a thermal step which would adverseyyaffect the functionality of the CBRAM memory elements.

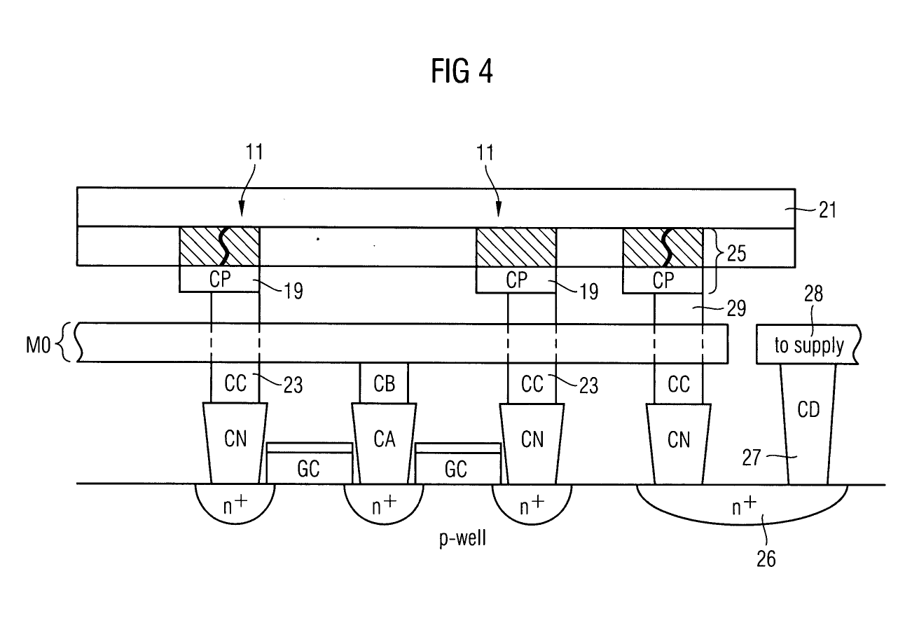

FIG. 4 shows a cross-section of a memory cell array of an integrated memory circuit according to a first embodiment of the present invention. The same reference numerals define elements having the same or a similar function as previously described with respect to FIG. 3. The embodiment shown in FIG. 4 includes two memory cells. As compared to the prior art shown in FIG. 3, the through-via to the second metallization layer above the connecting plate has been eliminated since the manufacture of which is incompatible due to the process parameters applicable for CBRAM memory elements. Instead, contacting of the connecting plate 21 is provided by a connecting element 25 which is configured similarly to the CBRAM memory elements 11 and may be manufactured by using the same process steps. The connecting element 25 as well as the memory elements 11 is connected with a conductive area 26 via a suitable further through-via 29, the conductive area 26 being provided as a doping region in the substrate surface and being connected to the conductor element 28 via a further through-via 27. The conductor element 28 may be formed in the same metallization layer as the bit line BL, namely in the first metallization layer M0. The conductive region 26 may be produced by means of the same process steps as the doping regions 14. The further through-via 29 between the conductive region 26 and the connecting element 25 may be produced in the same process steps as the through-vias 23 between the doping regions 14 and the first contact regions 19 of the CBRAM memory elements 11. In one embodiment, a memory cell array may include a plurality of connecting elements 25 and associated further through-vias 29 and conductive regions 26.

By using a connecting element 25 which is configured similarly to the CBRAM memory elements 11, the reference potential may be applied to the connecting plate 21 in a simple manner without the requirement of producing a further metallization layer after depositing the connecting plate 21 or carrying out a further process step which is incompatible with the already formed CBRAM memory elements. The connection of the connecting plate 21 with conductor element 28 provided in the first metallization layer M0 and insulated from the bit line BL can be carried out by utilizing the process steps for forming the through-vias and the conductive regions already required for manufacturing the CBRAM memory cells, resulting in that the number of additional steps for realizing the connection between the connecting plate and the conductor element may be reduced. The conductor element 28 thereby serves as a potential source or as an access to a potential source (not shown).

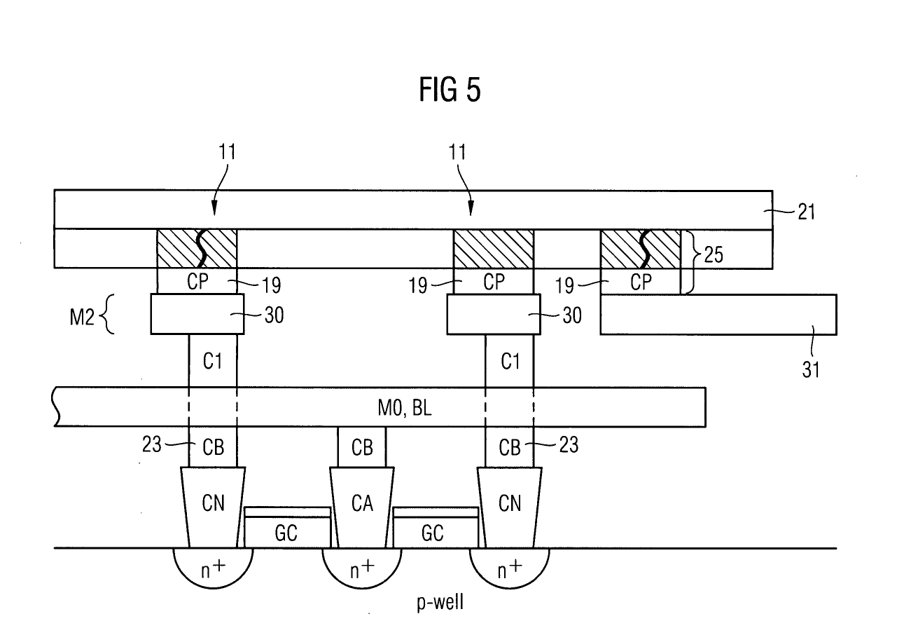

FIG. 5 shows a cross-section through an integrated memory circuit according to a further embodiment of the present invention. The integrated memory circuit of FIG. 5 differs from the memory circuit of FIG. 4 in that a third metallization layer M2 is provided between the first metallization layer M0 and the layer structure in which the CBRAM memory elements 11 and the connecting element 25 are formed. The third metallization layer M2 is patterned in such a way that it is in direct connection with the first contact region 19 of the CBRAM memory elements 11 (via conductor elements 30) and with the correspondingly assigned doping regions 14 via the through-via 23. Furthermore, a conductor element 31 is provided in the third metallization layer M2, which is in direct connection with the first contact region 19 of the connecting element 25 and serves to provide the reference potential for the connecting plate 21. In this case, the provision of the reference potential does not have to be carried out via the conductive area 26 in the substrate 13 (for the embodiment shown in FIG. 4), but is effected directly from the conductor element 31 of the third metallization layer M2 via the connecting element 25 to the connecting plate 21, so that a lower resistive contact (as compared to the embodiment shown FIG. 4) of the connecting plate may be achieved.

The inventive integrated memory circuits may be produced by means of conventional process steps whereby at first the doping regions 14, 26 are formed in the substrate and subsequently the structures required for forming the selection transistors 12 are arranged. Eventually, corresponding through-vias 18, 23, 29 and a desired number of metallization layers M0, M1, M2 (or more) are provided to ensure sufficient wiring of the memory cells and of the peripheral electronics. Then the process steps for depositing the CBRAM memory elements 11 or the connecting element 25 are carried out, so that the solid electrolyte is deposited at least at the positions of the CBRAM memory elements 11 and the connecting element 25. Thereupon, a conductive layer, such as a metal layer, is deposited forming the connecting plate 21. Thus, the required process steps in which the process means, temperatures, pressures, etc., which may be detrimental to the functionality of the memory elements, are carried out prior to the forming of the memory elements.

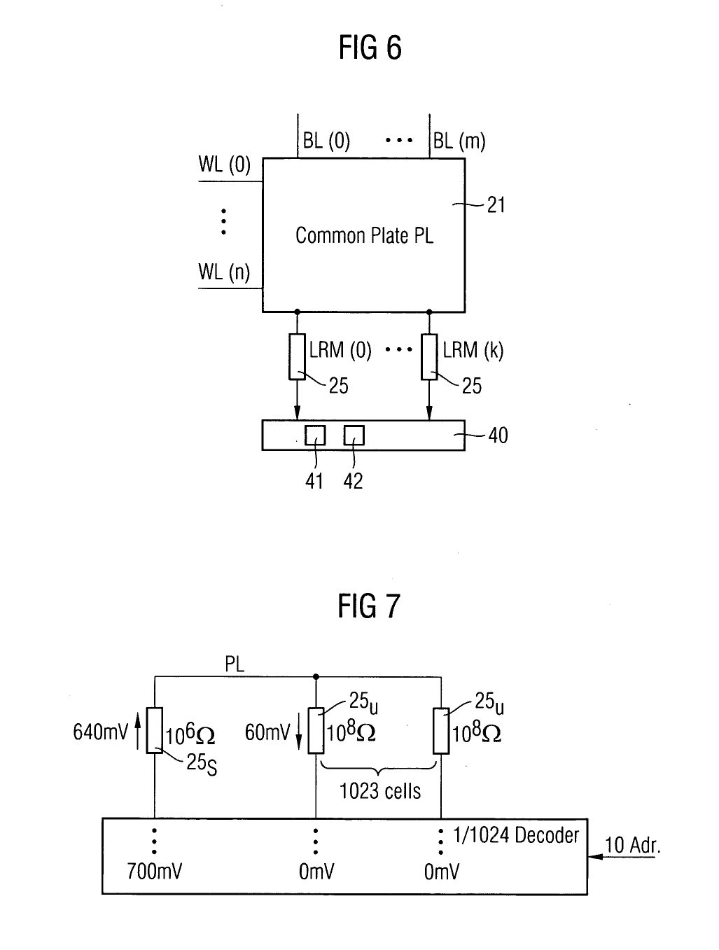

FIG. 6 is a schematic top view of the connecting plate (or common plate) above the memory cell array which is connected to the reference potential by a plurality of connecting elements 25. Particularly in the case of CBRAM elements provided as connecting elements 25, these are typically in a high resistive state after their production, i.e., approximately 10⁸Ω, with essentially no conductive path built up in the solid electrolyte. To ensure that a sufficient current can flow from and onto the connecting plate 21 when writing to or reading out from the memory cells, the reference potential needs to be connected to the connecting plate 21 via as low a resistance as possible. Therefore, it is necessary to set the connecting elements 25 to a low resistive state. In one embodiment, this is effected in an initializing process which is carried out by an initializing unit 40. For the embodiment shown in FIG. 5, the initializing unit 40 is connected to the conductor elements 31 which are coupled to the connecting elements 25. Similarly for the embodiment shown in FIG. 4, the initializing unit 40 may connected to the conductor elements 28 which are coupled to the connecting elements 25. The initializing unit 40 performs an initializing process in which, at first, a selection unit 41 selects one of the connecting elements 25 and applies a programming voltage between the first contact region 19 of the selected connecting element 25 and the first contact regions 19 of the unselected connecting elements 25, so that the selected connecting element is transferred from a high resistive to a low resistive state. The application of the programming voltage is performed by means of a programming unit 42.

FIG. 7 shows the voltage situation in an exemplary initializing process during the programming of a first of the connecting elements. A first connecting element 25ₛ is selected and connected to the other unselected connecting elements 25ᵤ by means of the connecting plate PL. The programming potential is applied between the first contact of the first connecting element 25ₛ and the first contact of the unselected connecting elements 25ᵤ, whereby due to the parallel connection of the unselected connecting elements, the total resistance of the unselected connecting elements is significantly lower than the resistance of the selected connecting elements 25ₛ. Since the selected connecting element 25ₛ and the non-selected connecting elements 25ᵤ are switched as a voltage divider, a higher voltage acts upon the selected connecting element than upon the unselected connecting elements 25ᵤ. The programming voltage is selected in such a way that the voltage acting upon the selected connecting element 25ₛ is sufficiently high to bring the selected connecting element 25ₛ from a high resistive state to a low resistive state. The voltage drop across the unselected connecting elements 25ᵤ, however, is not sufficient for setting these to the low resistive state. Of course, more than one of the connecting elements may be selected to speed up the initializing process. However, the voltage drop across the selected connecting elements 25ₛ needs to be sufficiently high to change their programming state from the high resistive to the low resistive state. This is achieved by choosing the number of selected connecting elements 25ₛ in such a way that the total resistance is significantly higher than the total resistance of the unselected connecting elements 25ᵤ, for example, by a factor 2 or more. This initialization method may be repeated until each of the connecting elements 25 has been transferred from a high resistive to a low resistive state. Furthermore, the initializing unit may provide a sufficiently high programming voltage respectively to each of a plurality of connecting elements 25 selected for initialization such that when the programming voltage is applied, a similar voltage acts upon each one of the connecting elements, this voltage being sufficiently high to set all of the selected connecting elements 25ₛ from the high resistive state to the low resistive state at the same time.

While the foregoing is directed to embodiments of the present invention, other and further embodiments of the invention may be devised without departing from the basic scope thereof, and the scope thereof is determined by the claims that follow.

What is claimed is:

1. An integrated memory circuit for storing information, comprising:
a memory cell having a memory element with a first contact for connecting the memory element to a write/read unit and a second contact for connecting the memory element to a reference potential provided by a potential source; and
a connecting element having a programmable resistance connected between the potential source and the second contact of the memory cell.

2. The memory circuit of claim 1, wherein the memory element is configured with a programmable resistance which is programmable to one of a high resistive state and a low resistive state.

3. The memory circuit of claim 2, wherein the connecting element is configured with a programmable resistance which is programmable to one of a high resistive state and a low resistive state.

4. The memory circuit of claim 3, wherein at least one of the memory element and the connecting element is configured as one of a magneto-resistive element, a phase change element and a CBRAM element.

5. The memory circuit of claim 1, wherein the memory element and the connecting element are arranged in a first layer structure over a substrate for forming the integrated memory circuit.

6. The memory circuit of claim 5, further comprising:
a bit line coupled to a first contact of the memory element; and
a conductor element connected between the potential source and the connecting element;
wherein the bit line and the conductor element are formed in a second layer structure which is arranged between the first layer structure and a substrate surface.

7. The memory circuit of claim 6, further comprising:
a selection transistor formed at the substrate surface connected between the bit line and the first contact of the memory element.

8. The memory circuit of claim 7, wherein the connecting element is coupled to the bit line via a conductive region provided on the substrate surface, the conductive region configured as one of a source region and drain region of the selection transistor.

9. The memory circuit of claim 5, wherein
a first contact of the memory element is coupled to a conducting region;
a second contact of the memory element is connected to the potential source via a conductor element; and
the conducting region and the conductor element are formed in a second layer structure.

10. The memory circuit of claim 9, further comprising:
a selection transistor provided at a substrate surface, wherein the memory element is coupled to a bit line formed in a third layer structure via the selection transistor and wherein the third layer structure is arranged between the second layer structure and the substrate surface.

11. The memory circuit of claim 10, wherein the connecting element is coupled to the conductor element without crossing the third layer structure.

12. The memory circuit of claim 1, wherein a plurality of memory cells are provided, each memory cell having a first contact and a second contact; and further comprising:
a common conductive connecting unit connected to the second contact each memory cell.

13. The memory circuit of claim 12, further comprising:
a plurality of connecting elements connected to the common connecting unit to apply the reference potential to the common connecting unit.

14. The memory circuit of claim 13, wherein the plurality of connecting elements is connected to the common connecting unit at various positions such that when a current flows through a first set of the memory elements, a voltage drop over an area of the common connecting unit is less than a predetermined value.

15. The memory circuit of claim 13, wherein the connecting elements are configured as initially high resistive CBRAM elements, and further comprising:
an initializing unit coupled to the first contacts of the connecting elements to set the connecting elements from the initially high resistive state to a low resistive state in an initializing process.

16. The memory circuit of claim 15, wherein the initializing unit comprises:
a selection unit for selecting one or more connecting elements in the high resistive state; and
a programming unit for applying a programming potential between the respective first contact of the selected one or more connecting elements and the first contacts of a plurality of unselected connecting elements.

17. A method for initializing an integrated memory circuit comprising a plurality of memory cells connected to a plurality of connecting elements respectively, each connecting element having a programmable resistance, the method comprising:
selecting one or more connecting elements in a high resistive state for programming to a low resistive state; and
applying a programming potential between a respective first contact of the selected one or more connecting elements and the first contacts of a plurality of unselected connecting elements.

18. The method of claim 17, further comprising:
repeating the selecting and applying steps to program the connecting elements that are in a high resistive state to a low resistive state.

19. The method of claim 17, wherein the programming potential is selected such that a voltage drop occurs over the selected one or more connecting elements, the voltage drop being sufficient for setting each selected connecting element to a low resistive state.

20. A method for manufacturing an integrated memory circuit, comprising:
providing a substrate;
manufacturing one or more conductor layers to form a bit line and a conductor element which is connectable to provide a reference potential, wherein the conductor element is isolated from the bit line;
forming a connecting element with a programmable resistance, the connecting element having a first contact and a second contact, wherein the first contact is coupled to the conductor element; and
forming a memory element having a first contact and a second contact, wherein the first contact of the memory element is coupled to the bit line and wherein the second contact of the memory element is connected to the second contact of the connecting element.

21. The method of claim 20, wherein the memory element is configured with a programmable resistance which is programmable to one of a high resistive state and a low resistive state.

22. The method of claim 21 wherein the connecting element and the memory element are formed during a common manufacturing step in a first layer structure on the substrate.

23. The method of claim 22, further comprising:
initializing the connecting element is to a low resistive state during a programming step.

24. The method of claim 23, wherein the bit line and the conductor element are formed in a common manufacturing step in a second layer structure arranged between the first layer structure and a substrate surface.

25. The method of claim 24, further comprising:
forming a selection transistor in the substrate, wherein the memory element is coupled to the bit line via the selection transistor.

26. The method of claim 24, further comprising:
forming a conductive region in the substrate in a common manufacturing step for forming the selection transistor, wherein the connecting element and the conductor element are coupled to each other via the conductive region.

27. The method of claim 22, further comprising:
forming a conducting region and the conductor element in one of the conductor layers as a second layer structure between the first layer structure and a substrate surface;
wherein the memory element is formed on the conducting region such that the first contact of the memory element is connected to the conducting region; and
wherein the connecting element is formed on the conductor element such that the first contact of the connecting element is connected to the conductor element.

28. The method of claim 27, further comprising:
forming a selection transistor in the substrate;
forming a bit line in a third layer structure, the third layer structure arranged between the second layer structure and the substrate surface, wherein the memory element is coupled to the bit line via the selection transistor.

29. The method of claim 28, wherein the connecting element is connected to the conductor element without crossing the third layer structure.

30. The method of claim 20, wherein a plurality of memory cells are provided, the respective memory elements of which are connected to each other by their second contacts.

31. The method of claim 30, wherein a plurality of connecting elements are provided to connect the reference potential to the second contacts of the memory elements.

32. The method of claim 31, further comprising:
forming a common connecting unit connected to the second contacts of the memory elements, wherein the connecting elements are connected to the common connecting unit at various positions.

33. The method of claim 32, further comprising:
performing an initializing process to program the connecting elements from a high resistive state to a low resistive state.

34. The method of claim 33, wherein the initializing process comprises:
selecting one or more connecting elements in a high resistive state for programming to a low resistive state; and
applying a programming potential between the respective first contact of the selected one or more connecting elements and the first contacts of a plurality of unselected connecting elements.

35. The method of claim 34, wherein the selecting step and the applying step are repeated until all of the connecting elements are set to a low resistive state.
